(19) United States
(12) Patent Application Publication
(10) Pub. No.: US 2015/0247894 A1
(43) Pub. Date: Sep. 3, 2015

(54) TEMPERATURE CONTROL SYSTEM

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: YI-LIANG LI, Wuhan (CN); SHU-QI WU, Wuhan (CN); YU-LIN LIU, Wuhan (CN)

(21) Appl. No.: 14/525,516

(22) Filed: Oct. 28, 2014

(30) Foreign Application Priority Data
Feb. 28, 2014 (CN) 201410070247.0

(51) Int. Cl. G01R 31/28

(52) U.S. Cl. CPC G01R 31/2874

(57) ABSTRACT

A temperature control system for a test chamber includes a control circuit, a temperature increasing circuit, and a temperature decreasing circuit. The control circuit detects a temperature in the test chamber, compares the temperature with a predetermined temperature, and outputs a first control signal when the temperature is lower than the predetermined temperature. The temperature increasing circuit receives the first control signal, and heats the test chamber in accordance therewith. The control circuit outputs a second control signal to the temperature when the temperature in the test chamber is higher than the predetermined temperature, the temperature decreasing circuit receives the second control signal, and cool the test chamber according to the second control signal to decrease the temperature in the test chamber.

### CROSS-REFERENCE TO RELATED APPLICATIONS

This application claims priority to Chinese Patent Application No. 201410070247.0 filed on Feb. 28, 2014, the contents of which are incorporated by reference herein.

### FIELD

The subject matter herein generally relates to a temperature control system.

### BACKGROUND

The performance of electrical devices such as computers, servers, notebooks and so on at different temperatures (thermal performance) is a significant concern. Thermal performance reflects an operational state of the electrical device in different temperature environments. When the thermal performance of an electrical device is tested, a simulation of different temperature environments is needed.

### BRIEF DESCRIPTION OF THE DRAWINGS

Implementations of the present technology will now be described, by way of example only, with reference to the attached figures.

FIG. 1 is a block diagram of an embodiment of a temperature control system.

FIG. 2 is a circuit diagram of the temperature control system of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

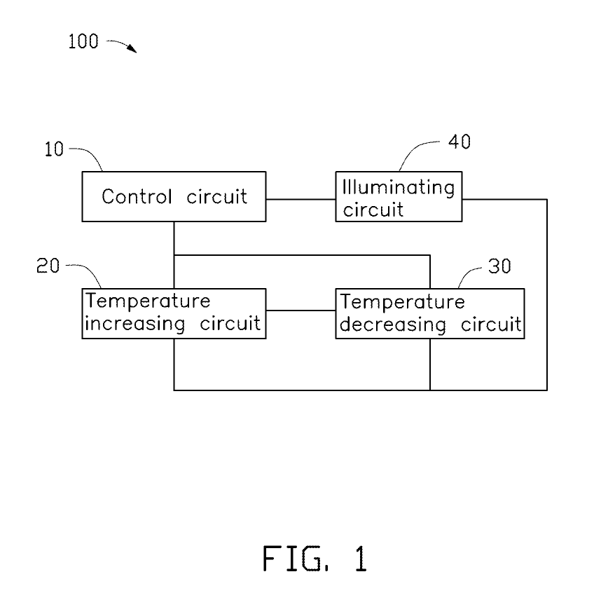

FIG. 1 illustrates a temperature control system for a test chamber 100 in accordance with an embodiment. The temperature control system includes a control circuit 10, a temperature increasing circuit 20, a temperature decreasing circuit 30, and an illuminating circuit 40.

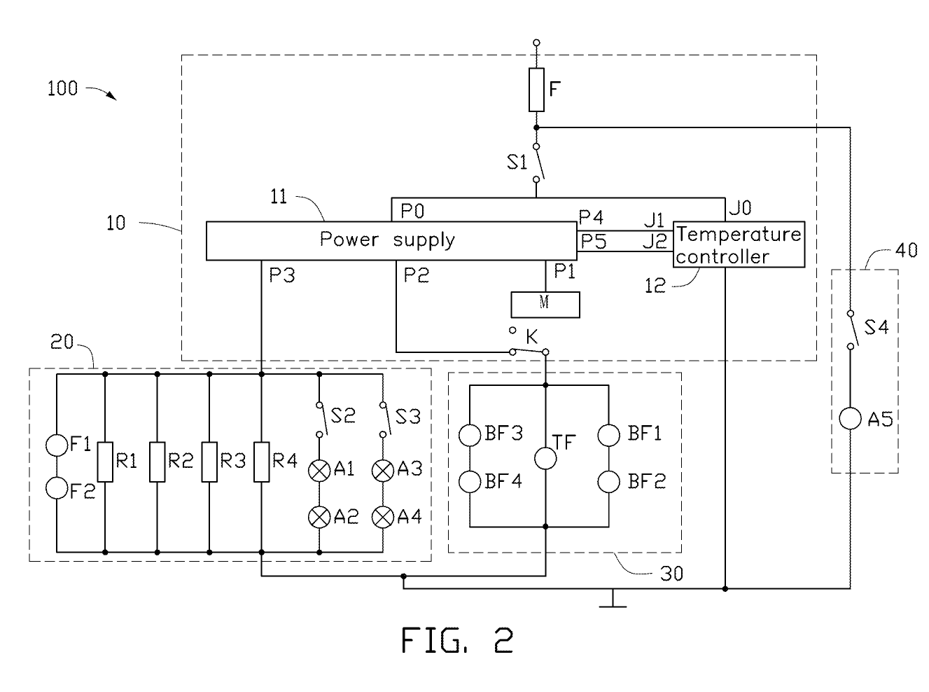

FIG. 2 illustrates the control circuit 10 includes a fuse F, a first switch S1, a power supply 11, a relay member, and a temperature controller 12. The power supply 11 includes a first power input terminal P0, a first power output terminal P1, a second power output terminal P2, a third power output terminal P3, a control signal input terminal P4, and a first ground terminal P5. The temperature controller 12 includes a second power input terminal J0, a control signal output terminal J1, and a second ground terminal J2. The relay member includes a winding unit M and a switch unit K. The switch unit K includes a first terminal, a second terminal, and a third terminal.

A first terminal of the fuse F receives an AC voltage. A second terminal of the fuse F is electrically coupled to a first terminal of the first switch 51. A second terminal of the first switch S1 is electrically coupled to the first power input terminal P0 and the second power input terminal J0. The first power output terminal P1 is electrically coupled to the winding unit M.

The second power output terminal P2 is electrically coupled to the first terminal of the switch unit K. The second terminal of the switch unit K is ideal. The control signal output terminal J1 is electrically coupled to the control signal input terminal P4. The second ground terminal J2 is electrically coupled to the first ground terminal P5.

The temperature increasing circuit 20 includes a number of resistors R1-R4, a number of lamps A1-A4, two first fans F1, F2, and two second switches S2, S3. First terminals of the first fan F1, the number of resistors R1-R4, and the second switches S2, S3 are electrically coupled to the third power output terminal P3. A second terminal of the first fan F1 is grounded via the first fan F2. Second terminals of the number of resistors R1-R4 are grounded. A second terminal of the second switch S2 is grounded via the lamps A1 and A2 connected in series. A second terminal of the second switch S3 is grounded via the lamps A3 and A4 connected in series. In at least one embodiment, the number of resistors R1-R4 are heating resistors. The number of lamps A1-A4 are incandescent lamps. The two first fans F1, F2 are located at a bottom of the test chamber 100.

The temperature decreasing circuit 30 includes a second fan TF and a number of third fans BF1-BF4. First terminals of the second fan TF and the third fans BF1, BF3 are electrically coupled to the third terminal of the switch unit K. A second terminal of the second fan TF is grounded. A second terminal of the third fan BF1 is grounded via the third fan BF2. A second terminal of the third fan BF3 is grounded via the third fan BF4. In at least one embodiment, the second fan TF is located at a top of the test chamber 100. The number of third fans BF1-BF4 are located beside the number of resistors R1-R4 respectively.

The illuminating circuit 40 includes a third switch S4 and an lamp A5. A first terminal of the third switch S4 is electrically coupled to the second terminal of the fuse F. A second terminal of the third switch S4 is grounded via the lamp A5. In at least one embodiment, the lamp A5 is a fluorescent lamp.

In use, the first switch S1 is closed, the power supply 11 and the temperature controller 12 receives the AC voltage and are powered on. The temperature controller 12 detects a temperature in the test chamber 100. When the temperature in the test chamber 100 is lower than a predetermined temperature in the temperature controller 12, the control signal output terminal J1 of the temperature controller 12 outputs a heating control signal. The first power output terminal P1, the second power output terminal P2, and the third power output terminal P3 output power on signals respectively.

The winding unit M receives the power on signal from the first power output terminal P1 and is powered on. The switch unit K is closed. The second terminal and the third terminal of the switch unit K are electrically connected. The first terminal and the third terminal of the switch unit K are cut off. The second fan TF and the number of third fans BF1-BF4 can not receive the power on signal from the second power output terminal P2 and are powered off. The number of resistors R1-R4 and the two first fans F1, F2 receives the power on signal from the third power output terminal P3 and are powered on. The number of resistors R1-R4 heat in the test chamber 100. The temperature in the test chamber 100 is increased. The two first fans F1, F2 rotate and dissipate heat for the bottom of the test chamber 100.

In the working process, the second switches S2, S3 are selectively closed. The lamps A1, A2, and the lamps A3, A4 selectively receive the power on signal from the third power output terminal P3. The lamps A1, A2, or the lamps A3, A4 are powered on. The temperature in the test chamber 100 is increased to a required value.

When the temperature in the test chamber 100 is higher than the predetermined temperature in the temperature controller 12, the control signal output terminal J1 of the temperature controller 12 outputs a cooling control signal. The first power output terminal P1, and the third power output terminal P3 output power off signals respectively. The second power output terminal P2 outputs a power on signal.

The winding unit M can not receive the power on signal from the first power output terminal P1 and is powered off. The switch unit K is opened. The second terminal and the third terminal of the switch unit K are cut off. The first terminal and the third terminal of the switch unit K are electrically connected. The second fan TF and the number of third fans BF1-BF4 receive the power on signal from the second power output terminal P2 and are powered on. The number of resistors R1-R4 and the two first fans F1, F2 can not receive the power on signal from the third power output terminal P3 and are powered off. The number of third fans BF1-BF4 rotate and dissipate heat for the corresponding resistors R1-R4. The temperature in the test chamber 100 is decreased. The second fan TF rotate and dissipate heat for the top of the test chamber 100.

In the working process, the third switch S4 is closed as required, the lamp A5 receives the AC voltage and emits light in the test chamber 100. The fuse F protects the power supply 11 and the temperature controller 12 from being damaged when there is an over current in the system.

The embodiments shown and described above are only examples. Many details are often found in the art such as the other features of a printed circuit board. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A temperature control system for a test chamber, the control system comprising:
a control circuit configured to detect a temperature in the test chamber, compare the temperature with a predetermined temperature, and output a first control signal when the temperature is lower than the predetermined temperature;
a temperature increasing circuit configured to receive the first control signal, and heat the test chamber in accordance therewith; and
a temperature decreasing circuit,
wherein, the control circuit is configured to output a second control signal to the temperature when the temperature in the test chamber is higher than the predetermined temperature, the temperature decreasing circuit receives the second control signal, and cool the test chamber according to the second control signal to decrease the temperature in the test chamber.

2. The temperature control system of claim 1, wherein the control circuit comprises a power supply, a relay member, and a temperature controller; the power supply comprises a first power input terminal, a first power output terminal, a second power output terminal, and a control signal input terminal; the temperature controller comprises a second power input terminal and a control signal output terminal; the relay member comprises a winding unit and a switch unit; the switch unit comprises a first terminal and a second terminal; the first power input terminal and the second power input terminal receives an AC voltage respectively; the first power output terminal is electrically coupled to the winding unit; the second power output terminal is electrically coupled to the first terminal of the switch unit; the second terminal of the switch unit is ideal; and the control signal output terminal is electrically coupled to the control signal input terminal.

3. The temperature control system of claim 2, wherein the power supply further comprises a third power output terminal; the temperature increasing circuit comprises a resistor, a first lamp, a first fan, and a second switch; first terminals of the first fan, the resistor, and the second switch are electrically coupled to the third power output terminal; second terminals of the first fan and the resistor are grounded; and a second terminal of the second switch is grounded via the first lamp.

4. The temperature control system of claim 3, wherein the resistor is a heating resistor; the first lamp is an incandescent lamp; and the first fan is located at a bottom of the test chamber.

5. The temperature control system of claim 4, wherein the switch unit further comprises a third terminal; the temperature decreasing circuit comprises a second fan and a third fan; first terminals of the second fan and the third fan are electrically coupled to the third terminal of the switch unit; and second terminals of the second fan and the third fan are grounded.

6. The temperature control system of claim 5, wherein the second fan is located at a top of the test chamber; and the third fan is located beside the resistor.

7. The temperature control system of claim 6, wherein the control circuit further comprises a fuse and a first switch; a first terminal of the fuse receives the AC voltage; a second terminal of the fuse is electrically coupled to a first terminal of the first switch; and the second terminal of the first switch is electrically coupled to the first power input terminal and the second power input terminal.

8. The temperature control system of claim 6, further comprising an illuminating circuit; and the illuminating circuit receives the AC voltage, and emits light in the test chamber.

9. The temperature control system of claim 8, wherein the illuminating circuit comprises a third switch and a second lamp; a first terminal of the third switch is electrically coupled to the second terminal of the fuse; and a second terminal of the third switch is grounded via the second lamp.

10. The temperature control system of claim 9, wherein the second lamp is a fluorescent lamp.

11. A temperature control system for a test chamber, the control system comprising:
a control circuit configured to detect a temperature in the test chamber, compare the temperature with a predetermined temperature, and output a first control signal when the temperature is lower than the predetermined temperature;
a temperature increasing circuit configured to receive the first control signal, and heat the test chamber in accordance therewith;
an illuminating circuit configured to receive an AC voltage, and emit light in the test chamber; and
a temperature decreasing circuit,
wherein, the control circuit is configured to output a second control signal to the temperature when the temperature in the test chamber is higher than the predetermined temperature, the temperature decreasing circuit receives the second control signal, and cool the test chamber according to the second control signal to decrease the temperature in the test chamber.

12. The temperature control system of claim 11, wherein the control circuit comprises a power supply, a relay member, and a temperature controller; the power supply comprises a first power input terminal, a first power output terminal, a second power output terminal, and a control signal input terminal; the temperature controller comprises a second power input terminal and a control signal output terminal; the relay member comprises a winding unit and a switch unit; the switch unit comprises a first terminal and a second terminal; the first power input terminal and the second power input terminal receives the AC voltage respectively; the first power output terminal is electrically coupled to the winding unit; the second power output terminal is electrically coupled to the first terminal of the switch unit; the second terminal of the switch unit is ideal; and the control signal output terminal is electrically coupled to the control signal input terminal.

13. The temperature control system of claim 12, wherein the power supply further comprises a third power output terminal; the temperature increasing circuit comprises a resistor, a first lamp, a first fan, and a second switch; first terminals of the first fan, the resistor, and the second switch are electrically coupled to the third power output terminal; second terminals of the first fan and the resistor are grounded; and a second terminal of the second switch is grounded via the first lamp.

14. The temperature control system of claim 13, wherein the resistor is a heating resistor; the first lamp is an incandescent lamp; and the first fan is located at a bottom of the test chamber.

15. The temperature control system of claim 14, wherein the switch unit further comprises a third terminal; the temperature decreasing circuit comprises a second fan and a third fan; first terminals of the second fan and the third fan are electrically coupled to the third terminal of the switch unit; and second terminals of the second fan and the third fan are grounded.

16. The temperature control system of claim 15, wherein the second fan is located at a top of the test chamber; and the third fan is located beside the resistor.

17. The temperature control system of claim 16, wherein the control circuit further comprises a fuse and a first switch; a first terminal of the fuse receives the AC voltage; a second terminal of the fuse is electrically coupled to a first terminal of the first switch; and the second terminal of the first switch is electrically coupled to the first power input terminal and the second power input terminal.

18. The temperature control system of claim 17, wherein the illuminating circuit comprises a third switch and a second lamp; a first terminal of the third switch is electrically coupled to the second terminal of the fuse; and a second terminal of the third switch is grounded via the second lamp.

19. The temperature control system of claim 18, wherein the second lamp is a fluorescent lamp.
